(19) United States
(12) Patent Application Publication
(10) Pub. No.: US 2009/0057884 A1
(43) Pub. Date: Mar. 5, 2009

(54) Multi-Chip Package

(76) Inventors: Seah Sun Too, San Jose, CA (US); James Hayward, Santa Clara, CA (US)

Correspondence Address: TIMOTHY M HONEYCUTT ATTORNEY AT LAW, P O BOX 1577, CYPRESS, TX, 77410, US

(21) Appl. No.: 11/846,642

(22) Filed: Aug. 29, 2007

(51) Int. Cl. H01L 23/34; H01L 21/00

(52) U.S. Cl. 257/723; 438/107; 257/E23.181

(57) ABSTRACT

Various semiconductor chip packages and package lids are disclosed. In one aspect, a method of manufacturing is provided that includes forming a semiconductor chip package lid with a peripheral wall that defines a first interior space. A first bridge structure is formed in the first interior space. The first bridge structure is adapted to engage a surface of a substrate.

### BACKGROUND OF THE INVENTION

1. Field of the Invention

This invention relates generally to semiconductor processing, and more particularly to semiconductor chip packages, components thereof and method of making the same.

2. Description of the Related Art

Heat is an unwanted by-product of most electronic devices. Integrated circuits, such as various types of processors, can be particularly susceptible to heat-related performance problems or device failure. Packaged integrated circuits, such as semiconductor chips, consist of a base substrate to which a semiconductor die is mounted and a lid that is seated on the substrate and over the die. The problem of cooling packaged semiconductor chips has been addressed in a variety of ways, such as cooling fans, heat fins and even liquid cooling systems.

In the past few years, the size and power consumption of integrated circuits has climbed to the point where designers have turned to other methods of managing heat propagation for packaged semiconductor chips. One of these techniques involves using a metal lid for the package. Metal lids have the advantage of generally higher conductivities than comparably sized non-metallic lids and thus carry greater heat loads away from an integrated circuit. Of course, to ensure a conductive heat transfer pathway from the integrated circuit, designers early on placed a thermal paste between the integrated circuit and the lid.

One type of conventionally-used thermal interface material consists of a polymer, such as silicone rubber, mixed with thermally conductive metal particles, such as copper or aluminum. The polymer provides a compliant film between the integrated circuit and the overlying lid and easily provides a matrix to hold the thermally conductive metal particles. The thermal resistance of the thermal interface material is dependent on, among various things, the spacing between the metallic particles. More recently, designers have begun to turn to metallic thermal interface materials. The effectiveness of organic or metallic thermal interface materials in transporting heat is dependent on a uniform bonding to the semiconductor chip and the overlying lid.

A typical conventional packaged semiconductor chip consists of a laminate of several layers of different materials. From bottom to top, a typical package consists of a base substrate, a die underfill material, an array of solder bumps, the silicon die, the thermal interface material and the lid. Each of these layers generally has a different coefficient of thermal expansion (CTE). In some cases, the coefficients of thermal expansion for two layers, such as the underfill material and the silicon die, may differ by a factor of ten or more. Materials with differing CTE's strain at different rates during thermal cycling. The differential strain rates tend to produce warping of the package substrate and the silicon die. If the warping is severe enough, several undesirable things can occur. First, the semiconductor can be warped to a point where the underlying solder bumps delaminate and cause electrical failure. Second, the thermal interface material can be stretched to the point of delamination from either the semiconductor chip, the lid or both. The thermal resistance of the delaminated area can skyrocket.

Conventional multi-chip devices can be susceptible to differential CTE substrate warping. In conventional multi-chip devices, both the substrates and bathtub or “top hat” style lids tend to be oblong. The conventional lids have a continuous internal space that is designed to accommodate two semiconductor chips mounted side-by-side on the substrate. As a result of the large internal space of the lid, the central region of the package substrate is unfettered structurally and may undergo significant thermal strains. The warping can cause delamination of the thermal interface materials of the two dice, particularly near the central region of the substrate.

The present invention is directed to overcoming or reducing the effects of one or more of the foregoing disadvantages.

### SUMMARY OF THE INVENTION

In accordance with one aspect of the present invention, a method of manufacturing is provided that includes forming a semiconductor chip package lid with a peripheral wall that defines a first interior space. A first bridge structure is formed in the first interior space. The first bridge structure is adapted to engage a surface of a substrate.

In accordance with another aspect of the present invention, a method of manufacturing is provided that includes coupling plural semiconductor chips to a surface of a substrate and coupling a lid to the substrate. The lid has a peripheral wall that defines a first interior space. A first bridge structure is in the first interior space to engage the surface of the substrate.

In accordance with another aspect of the present invention, an apparatus is provided that has a semiconductor chip package lid that includes a peripheral wall which defines a first interior space. A first bridge structure is coupled to the lid in the first interior space. The first bridge structure is adapted to engage a surface of a substrate.

In accordance with another aspect of the present invention, an apparatus is provided that includes a first substrate that has a surface and plural semiconductor chips coupled to the surface of the first substrate. A lid is coupled to the substrate. The lid has a peripheral wall that defines first interior space, and a first bridge structure in the first interior space to engage the surface of the substrate.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary conventional multi-chip package;

FIG. 2 is a sectional view of FIG. 2 taken at section 2-2;

FIG. 3 is a plan view of the substrate of the conventional package depicted in FIGS. 1 and 2;

FIG. 4 is a pictorial of a lid of the conventional package depicted in FIGS. 1 and 2 but shown inverted;

FIG. 5 is a pictorial view of an exemplary embodiment of a package lid shown in an inverted position;

FIG. 6 is a sectional view of an exemplary embodiment of a semiconductor chip package;

FIG. 7 is a plan view of an exemplary substrate of the type depicted in FIG. 6;

FIG. 8 is a pictorial view of an alternate exemplary embodiment of a package lid shown in an inverted position;

FIG. 9 is a pictorial view of another alternate exemplary embodiment of a package lid shown in an inverted position; and

FIG. 10 is a pictorial view of an exemplary embodiment of a semiconductor chip package partially exploded from a substrate.

### DETAILED DESCRIPTION OF SPECIFIC EMBODIMENTS

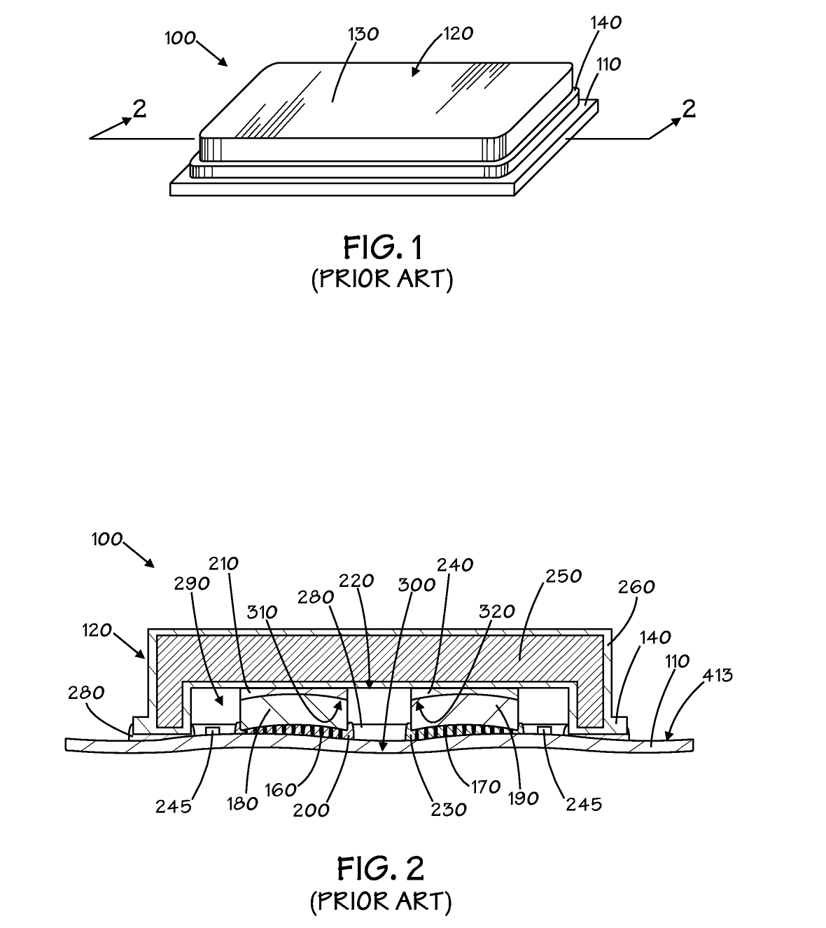

In the drawings described below, reference numerals are generally repeated where identical elements appear in more than one figure. Turning now to the drawings, and in particular to FIG. 1, therein is shown a pictorial view of an exemplary conventional multi-chip package 100 that includes a base substrate 110 and a top hat lid 120 seated on the substrate 110. The lid 120 consists of a crown portion 130 and a somewhat peripherally larger brim or flange 140 that is actually seated on the package substrate 110. Additional detail regarding the conventional package 100 may be understood by referring now also to FIG. 2, which is a sectional view of FIG. 1 taken at section 2-2. The substrate 110 is configured as a land grid array. Due to various mechanisms to be described in more detail below, the substrate 110 has a warped profile that is somewhat exaggerated in FIG. 2 for ease of readability. Structurally speaking, the substrate 110 is an organic substrate that consists of a plurality of built-up layers of epoxy and interconnect layers that establish electrical pathways between the conductor pins 150 and solder bumps 160 and 170 that are electrically connected to respective semiconductor chips 180 and 190 mounted to the substrate 110. The semiconductor chip 180 is provided with an underfill material 200 that is designed to address issues of differential CTE between the chip 180 and the substrate 110. A thermal interface material 210 is provided between the semiconductor chip 180 and the under surface 220 of the lid 120. The semiconductor chip 190 is similarly provided with an underfill material 230 and an overlying thermal interface material 240. Various capacitors 245 may be coupled to the substrate 110.

The lid 120 consists of a copper core 250 surrounded by a nickel jacket 260. The brim or flange 140 of the lid 120 defines a downwardly facing surface 270 that is secured to the substrate 110 by way of an adhesive bead 280. Note that because of the location of section 2-2, some portions of the bead 280 appear in section while another does not. The lid 120 includes a continuous interior space 290 that accommodates the semiconductor chips 180 and 190 and the capacitors 245.

As noted above, the substrate 110 has a wave-like profile due to warping. The warping is due to mismatches in the CTE's of the substrate 110, the underfill materials 200 and 230, the semiconductor chips 180 and 190 and possibly the thermal interface materials 210 and 240. The warping of the substrate 110 is dependent on temperature. At elevated temperatures, the substrate 110 has a wavy profile. At temperatures between about 100° C. and 150° C., the substrate 110 may actually begin to flatten or warp downward, which warps the central region 300 downward. The substrate 110 is not the only structure that is warped. The semiconductor chips 180 and 190 are subjected to the same type of warping, which is shown somewhat exaggerated in FIG. 2 for ease of readability. The warping of the substrate 110 and the semiconductor dice 180 and 190 produces some stretching of the solder bumps 160 and 170, which is again shown in a somewhat exaggerated fashion in FIG. 2.

As noted in the Background section hereof, the warping of the substrate 110 may be particularly troubling in the central region 300. This centralized warping may be worrisome since it may produce either poor or partial wetting, or delamination of a thermal interface material 210 and 240, particularly at the locations 310 and 320. Any instances of thermal interface material delamination normally produce undesirable hot spots, which can affect device performance and life span.

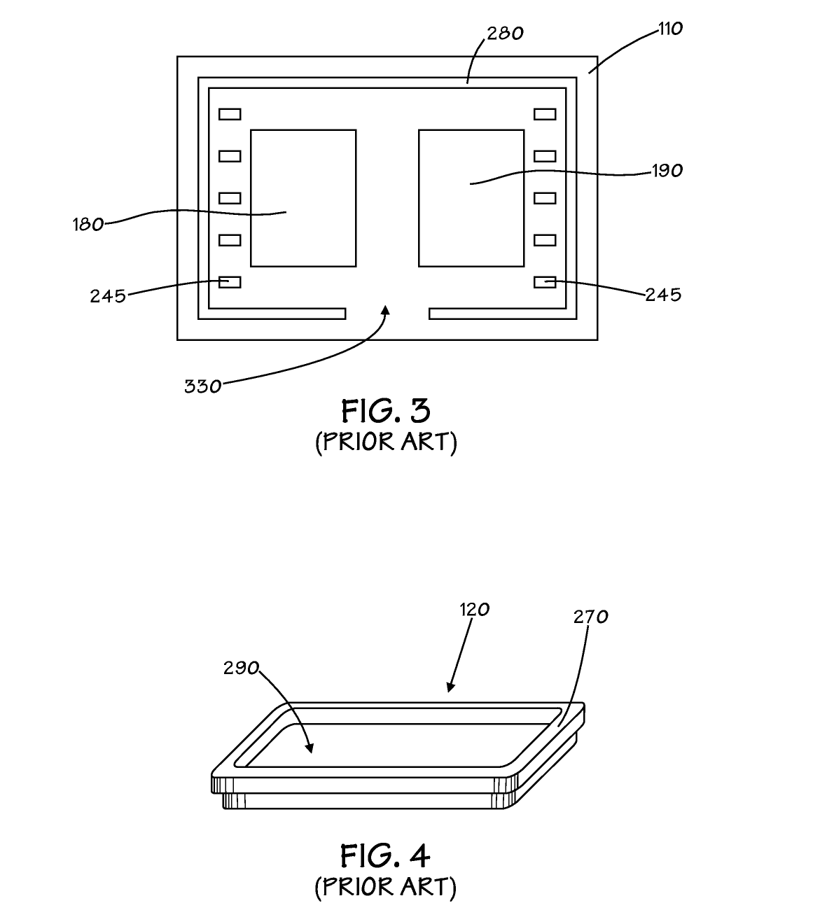

A few additional details regarding the conventional package 100 may be understood by referring now also to FIGS. 3 and 4. FIG. 3 is a plan view of the substrate 110 with the lid 120 depicted in FIGS. 1 and 2 removed. FIG. 4 is a pictorial view of the lid 120 removed and flipped over to reveal the peripheral surface 270 and the interior space 290. Referring again to FIG. 3, the adhesive bead 280 includes a discontinuity 330 to allow for outgassing. During assembly, the lid 120 depicted in FIG. 4 is flipped over so that the peripheral surface 270 seats on the adhesive bead 280 and thus the lid 120 thereafter covers the semiconductor chips 180 and 190 depicted in FIG. 3 as well as the capacitors 245. It should be noted that the conventional lid 120 depicted in FIG. 4 includes the interior space 290 that is completely open.

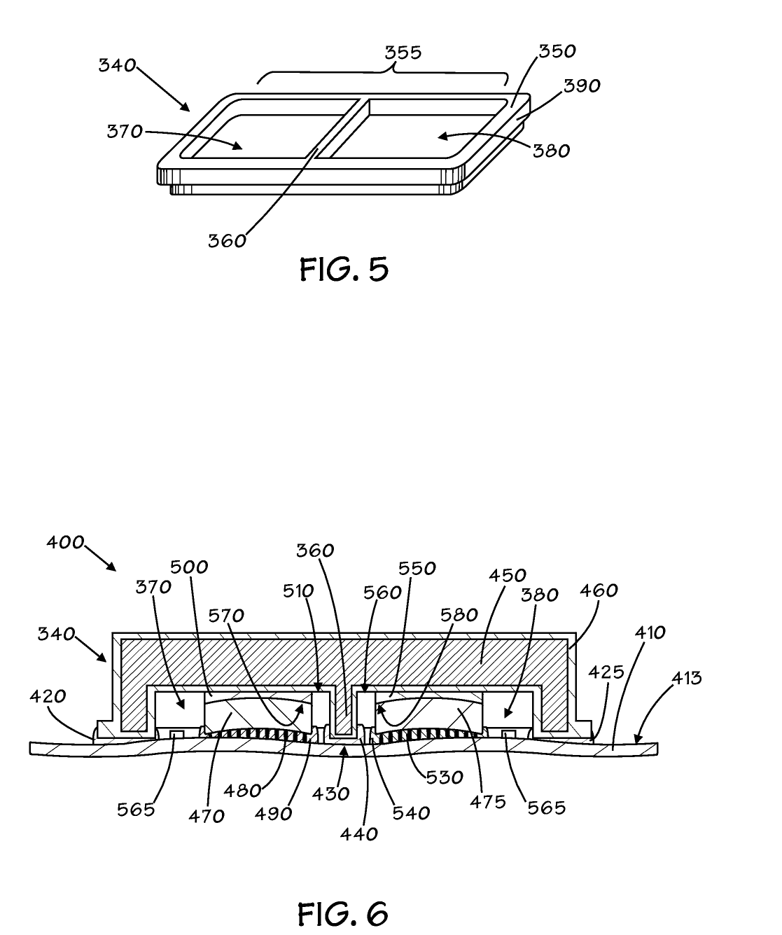

An exemplary embodiment of a package lid 340 that addresses the issues of central region substrate warping may be understood by referring now to FIGS. 5 and 6. FIG. 5 is a pictorial view of the exemplary embodiment of the package lid 340 shown upside down to reveal a peripheral wall 350 that is designed to seat on an adhesive bead as described in more detail below. The peripheral wall 350 defines an interior space 355. To address the problems of centralized substrate warping, the lid 340 is provided with a bridge structure 360 in the interior space 355 that is designed to engage a central portion of a substrate and thereby reduce the amount of centralized warping. In this illustrative embodiment, the bridge 360 subdivides the lid interior space 355 of the lid 340 into two interior spaces 370 and 380. The peripheral wall or surface 350 may be part of a flange or brim of the lid 340. The lid 340 is depicted as a top hat configuration, however, the skilled artisan will appreciate that other than a top hat configuration, such as a bathtub or other design may be used.

Attention is now turned to FIG. 6, which is a sectional view of an exemplary embodiment of a semiconductor chip package 400 that includes the lid 340 seated on a package substrate 410. More particularly, the lid 340 is seated on a surface 413 of the substrate 410. The substrate 410 may be organic, ceramic or the like. If organic, the substrate may be standard core, thin core or coreless, and composed of well-known epoxies and fillers or the like. The substrate 410 is depicted as a land grid array that has a plurality of socket that are not visible. However, the substrate 410 may be configured as a ball grid array, a pin grid array or other type of interconnect scheme. The peripheral surface 350 of the lid 340 is secured to the substrate 410 by way of an adhesive bead 420. Similarly, the bridge 360 engages the surface 413 at the central portion 430 of the substrate 410 and is secured thereto by way of an adhesive bead 440. The adhesive bead 440 may or may not be part of the adhesive bead 420. One example of a suitable adhesive for the beads 420 and 440 is a silicone-based thixotropic adhesive, which provides a compliant bond.

The lid 340 may be composed of well-known ceramics or metallic materials as desired. Some exemplary materials include nickel plated copper, anodized aluminum, aluminum-silicon-carbon, aluminum nitride, boron nitride or the like. In an exemplary embodiment, the lid 340 may consist of a copper jacket 450 surrounded by a nickel jacket 460. The interior spaces 370 and 380 accommodate respective semiconductor chips 470 and 475. The semiconductor chips 470 and 475 may be any of a myriad of different types of circuit devices used in electronics, such as, for example, microprocessors, graphics processors, application specific integrated circuits, memory devices or the like, and may be single or multi-core. The semiconductor chips 470 and 475 may be fabricated using silicon, germanium or other semiconductor materials. If desired, the chips 470 and 475 may be fabricated as semiconductor-on-insulator substrates. The chip 470 is mounted to the substrate 410 and electrically interconnected thereto by a plurality of solder structures 480. Other types of interconnects may be used to electrically connect the chip 470 to the substrate 410, such as, conductor pillars of copper or other conducting materials or other types of conductor structures. An underfill material 490 of epoxy resin or the like may be disposed between the chip 470 and the substrate 410 to address issues of differential CTE. A thermal interface material 500 may be interposed between the chip 470 and the lower surface 510 of the space 370. The thermal interface material 500 may be composed of polymeric materials such as, for example, silicone rubber mixed with aluminum particles and zinc oxide, or metallic materials, such as indium. Optionally, compliant base materials other than silicone rubber and thermally conductive particles other than aluminum may be used.

The interior space 380 accommodates the other semiconductor chip 475 that is electrically interconnected to the substrate 410 by way of plurality of solder structures or other structures 530. An underfill material 540 or the type described above may be provided between the chip 475 and the substrate 410 and serve the same function as the underfill material 490. Similarly, a thermal interface material 550 of the type described above may be positioned between the chip 475 and a lower surface 560 of the interior space 380. The interior spaces 370 and 380 accommodate plural passive devices 565, which maybe capacitors, inductors, resistors or the like.

The substrate 410 may still have the wave-like profile as depicted in FIG. 6. However, the presence of the bridge 360 that is coupled to the substrate 410 by way of the adhesive 440, restricts the downward warping of the central region 430 of the substrate 410. In this way, the risk of delamination of the thermal interface materials 500 and 550 is lowered, particularly near the locations 570 and 580.

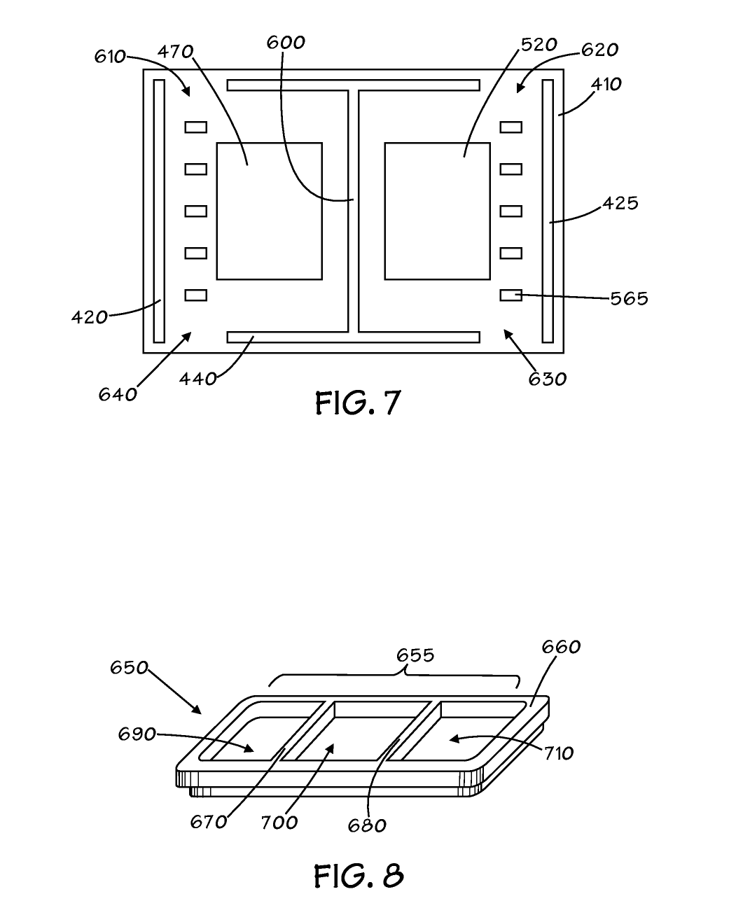

Additional details regarding the substrate 410 may be understood by referring now to FIG. 7, which is an overhead view. The semiconductor chips 470 and 520 are visible as well as the adhesive beads 420, 425 and 440. The plural passive devices 565 are also visible. The central portion 600 of the adhesive bead 440 is provided to engage the bridge 360 of the lid 340 depicted in FIG. 6. The gaps 610, 620, 630 and 640 provide areas for outgassing. The precise configuration of the beads 420, 425 and 440 is largely a matter of design discretion.

An alternate exemplary embodiment of a package lid 650 may be understood by referring now to FIG. 8, which is a pictorial view of the lid 650 flipped upside down to reveal a peripheral wall or surface 660 that defines an interior space 655 and two bridge structures 670 and 680 that divide the interior space 655 into three interior spaces 690, 700 and 710. This illustrative embodiment with three interior spaces 690, 700 and 710 can accommodate, for example, three semiconductor chips or groups of semiconductor chips as the case may be. The presence of the multiple bridges 670 and 680 can engage separate locations on a package substrate not shown in FIG. 8, but exemplified by the substrate 410 shown in FIG. 6, and thus provide the aforementioned warpage reduction. The skilled artisan will appreciate that the number of bridge structures may be subject to variation.

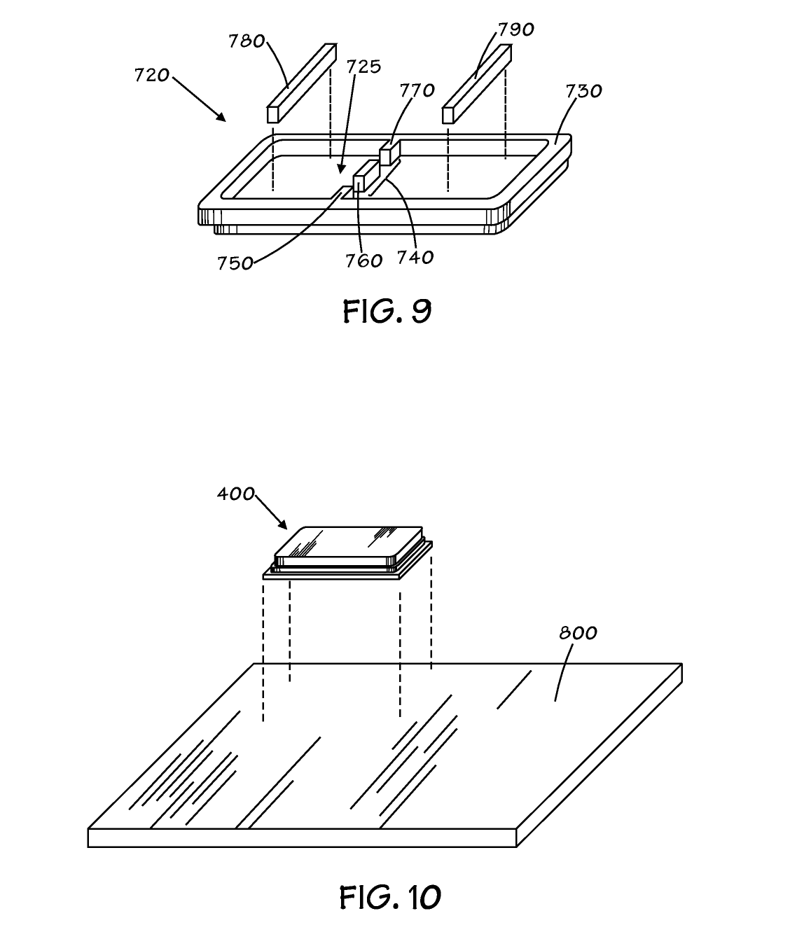

Another alternate exemplary embodiment of a package lid 720 is depicted in pictrial form in FIG. 9. In this illustrative embodiment, the lid 720 includes a peripheral wall or surface 730 that defines an interior space 725, and a bridge structure 740 that is divided into segments 750, 760 and 770. In addition, the lid 720 may be provided with discrete bridge structures 780 and 790 that may be connected to the lid 720 by adhesives, metallurgical bonding or other fastening techniques so as to subdivide the lid 720 into multiple interior spaces. Indeed, any of the embodiments disclosed herein may utilize a bridging structure that is either integral with the lid or configured as a separate member that may be fastened to the lid. If configured as discrete members, the bridge structures 780 and 790 may be composed of the same or of different materials than the lid 720 itself. The bridge structures for any of the disclosed embodiments may be rectangular or other shapes as desired.

The skilled artisan will appreciate a package, such as the package 400, may be coupled to another device, such as a substrate or printed circuit board. In this regard, FIG. 10 depicts a partially exploded pictorial view of the package 400 mounted to a printed circuit board 800. The printed circuit board 800 may be a motherboard, a circuit card, or some other type of printed circuit board.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a semiconductor chip package lid with a peripheral wall defining a first interior space; and
forming a first bridge structure in the first interior space, the first bridge structure being adapted to engage a surface of a substrate.

2. The method of claim 1, wherein the forming the first bridge structure comprises forming the first bridge structure integrally with the peripheral wall.

3. The method of claim 1, wherein the forming the first bridge structure comprises forming the first bridge structure and coupling the first bridge structure to the semiconductor chip package lid.

4. The method of claim 1, comprising forming a second bridge structure in the first interior space, the second bridge structure being adapted to engage the surface of the substrate.

5. The method of claim 4, wherein the forming the second bridge structure comprises forming the second bridge structure integrally with the peripheral wall.

6. A method of manufacturing, comprising:
coupling plural semiconductor chips to a surface of a substrate; and
coupling a lid to the substrate, the lid having a peripheral wall defining a first interior space, and a first bridge structure in the first interior space to engage the surface of the substrate.

7. The method of claim 6, wherein the first bridge structure divides the first interior space into a second interior space and a third interior space, the step of the coupling the lid comprising positioning the lid so that at least one of the plural semiconductor chips being located in the second interior space and another of the plural semiconductor chips being located in the third interior space.

8. The method of claim 7, wherein the coupling the lid comprises using an adhesive to secure the first bridge structure to the surface of the substrate.

9. The method of claim 6, comprising coupling the substrate to a printed circuit board.

10. The method of claim 6, comprising providing the lid with a second bridge adapted to engage the surface of the substrate.

11. An apparatus, comprising:
a semiconductor chip package lid including a peripheral wall defining a first interior space; and
a first bridge structure coupled to the lid in the first interior space, the first bridge structure being adapted to engage a surface of a substrate.

12. The apparatus of claim 11, wherein the first bridge structure is integral with the peripheral wall.

13. The apparatus of claim 11, wherein the first bridge structure a bridge structure comprises a member coupled to the lid.

14. The apparatus of claim 11, comprising a second bridge structure coupled to the lid in the first interior space, the second bridge structure being adapted to engage the surface of the substrate.

15. The apparatus of claim 11, wherein the lid comprises a metallic core covered by a metallic jacket.

16. An apparatus, comprising:
a first substrate having a surface;
plural semiconductor chips coupled to the surface of the first substrate; and
a lid coupled to the substrate, the lid having a peripheral wall defining a first interior space, and a first bridge structure in the first interior space to engage the surface of the substrate.

17. The apparatus of claim 16, wherein the first bridge structure divides the first interior space into a second interior space in which at least one of the plural semiconductor chips is located and a third interior space in which another of the plural semiconductor chips is located.

18. The apparatus of claim 16, wherein the lid is coupled to the substrate with an adhesive.

19. The apparatus of claim 16, comprising a printed circuit board coupled to the substrate.

20. The apparatus of claim 16, wherein the lid comprises a second bridge structure in the first interior space adapted to engage the surface of the substrate.
